(19) United States
(12) Patent Application Publication
(10) Pub. No.: US 2011/0122591 A1
(43) Pub. Date: May 26, 2011

(54) HYBRID FABRIC MATERIALS, AND STRUCTURAL COMPONENTS INCORPORATING SAME

(76) Inventors: Martyn John Hucker, Bristol (GB); Sajad Haq, Bristol (GB); Michael Dunleavy, Bristol (GB)

(21) Appl. No.: 13/002,938

(22) PCT Filed: Jul. 2, 2009
(86) PCT No.: PCT/GB09/01658

§ 371 Date: Jan. 6, 2011

(30) Foreign Application Priority Data
Jul. 8, 2008 (GB) 0812485.1

(51) Int. Cl. H05K 7/00; H05K 1/00; H01B 11/02

(52) U.S. Cl. 361/760; 174/250; 174/113 R

(57) ABSTRACT

Composite structural components are disclosed that include electrically conducting fibres providing signal power paths to electrical components disposed on or adjacent the material. The signal paths may therefore be embedded in the structural component. Also disclosed is a flexible or drapable fabric containing electrically conducting fibres for similar purposes, and materials for making up said structure and fabrics and methods for the production thereof.

This invention relates to electrical circuit assemblies and structural components incorporating the same, and in particular to fibre reinforced composite materials in which one or more of the fibres is electrically conducting to pass an electrical current. The invention also relates to fabrics made up of electrically conducting fibres.

Modern aircraft typically contain many miles of cabling which passes electric current, for example to supply power to equipment, to carry control signals, or to pass electronic data. Such cabling contributes to the weight of the vehicle, and furthermore is time-consuming to install and route. There is therefore a need to provide alternative ways of passing electric currents which are also ideally of low profile configuration. Moreover, as new technologies are developed for monitoring and control of a vehicle such as an aircraft, so the need to pass signals or power to or from components increases.

Accordingly, in one aspect, this invention provides a hybrid fabric material comprising a plurality of spaced electrically conducting fibres extending in a first direction and electrically isolated from other like conducting fibres, and a plurality of electrically insulating fibres extending in a second direction, thereby to define a material having a plurality of insulated electrically conducting tracks extending in a first direction.

In this manner existing fibre production techniques may be readily adapted to produce a fabric which contains conducting tracks within the material to provide an integral conducting structure for the passage of electrical current. The conducting tracks are discretely addressable.

In one arrangement, said fabric is woven and said spaced electrically conducting fibres are warp fibres and said insulating fibres extending in the second weave direction are weft fibres. Thus in production selected warp bobbins of non-conducting material e.g. glass, Kevlar® or the like in a conventional weave are replaced by bobbins of an electrically conducting fibre e.g. carbon. In preferred embodiments of the invention said electrically conducting warp fibres are interposed by electrically insulating fibres to provide a periodic or an aperiodic structure.

Any suitable electrically conducting fibres may be used for example one or more of carbon fibres, metal plated fibres, and metallised fibres.
The invention attends to a fibre composite material made up of a hybrid material as described above, and a matrix material. Advantageously the fibres are selected from those already commonly used in the production of fibre composite material, whose strength and boding properties in relation to the matrix materials used are known. The matrix material is preferably selected from polymeric, elastomeric, metal and ceramic materials or a mixture of one or more of these.

The fibre composite material may comprise a plurality of layers of hybrid material as described above, and at least one conductive fibre extending through the thickness of the composite material. The fibre composite material may be arranged such that electrical connections can be made to both ends of the conductive fibre. It will be noted that a plurality of fibres may be combined to form a conductive tow extending through the thickness of the fibre composite material. Several such conductive tows may be used such that a number of through thickness electrical connections can be made.

Although there is a very wide range of applications, one of particular interest is a fibre composite material of rigid sheet form defining a plurality of electrically conducting tracks each for the passage of data, power, control signals or a combination of one or more of these. For example the sheet of fibre composite material may be a surface element or panel of a vehicle.

In another application a transmission line for transmission of electrical signals includes a multilayer structure built up of a layer of hybrid material as described above and defining a plurality of insulated electrically conducting tracks, and one or more electrically insulating layers disposed adjacent to said hybrid weave material layer. The transmission line may include at least one layer of electrically insulating material provided to either side of said hybrid material layer thereby to sandwich said hybrid material layer. At least one screening layer of electrically conductive material may be disposed adjacent the outermost electrically insulating layer and remote from the hybrid material layer.

The electrical circuit assembly as described above may take many forms according to the particular application to which it is intended. Thus for example, the electrical circuit assembly may include electrical components which each have respective digital input/output terminals for inputting and/or outputting a digital signal, with the assembly providing a plurality of conducting fibres passing digital signals between said digital input/output terminals.

The invention is of course not limited to use with digital electronic components as the circuit assembly can comprise two spaced analogue electrical circuit components and indeed hybrid arrangements where the assembly includes analogue sensors which transmit or modulate a signal to/from a primarily digital component.

The term “electrically conducting” is relative and intended to be interpreted as meaning that a useful electrical signal is transmitted along a desired signal or power path. Like wise the term “electrically insulating” is relative and used to mean that the material has good insulating properties relative to the electrically conducting material.

The term “metal” is used to include not only pure metals but metal alloys, semiconductors and semi-metals.

In one arrangement, the conducting fibres may form part of an active sensor such as an antenna. Here the conducting fibres could pass signals to and/or from simple dipoles or arrays. These dipoles or arrays may be separate or they may comprise suitably configured electrically conducting fibres. In another arrangement, the conducting fibres may be configured to make up a frequency selective structure (FSS). In the latter case, a composite structure in accordance with the invention can be provided to serve e.g. as a radome with electrically conducting tracks spaced so as to be transparent to the wavelength of interest.

The invention further extends to a hybrid material comprising a plurality of electrically insulating fibres extending in first, warp direction, a plurality of electrically insulating fibres extending in a second, weft direction, and at least one electrically conducting fibre extending in a third direction generally perpendicular to the first and second directions, such that an electrical connection can be made across the hybrid material.

It is to be appreciated that any one electrically conducting fibre may readily be replaced by a tow of electrically conducting fibres.

The invention will be better understood by reference to the following description and Examples, reference being made to the accompanying drawings, in which:

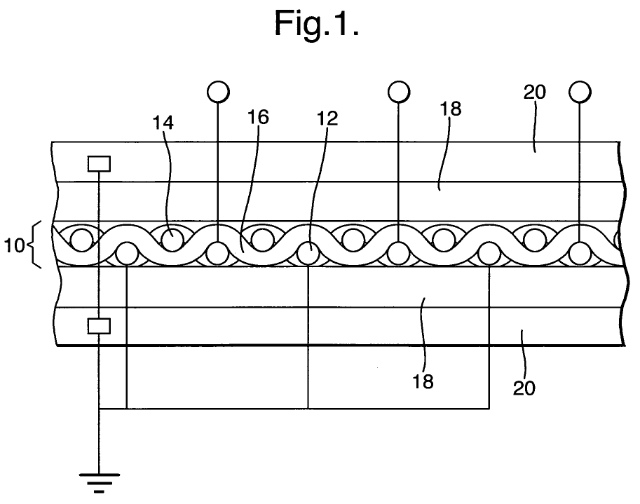

FIG. 1 is a schematic cross section through a hybrid weave of this invention;

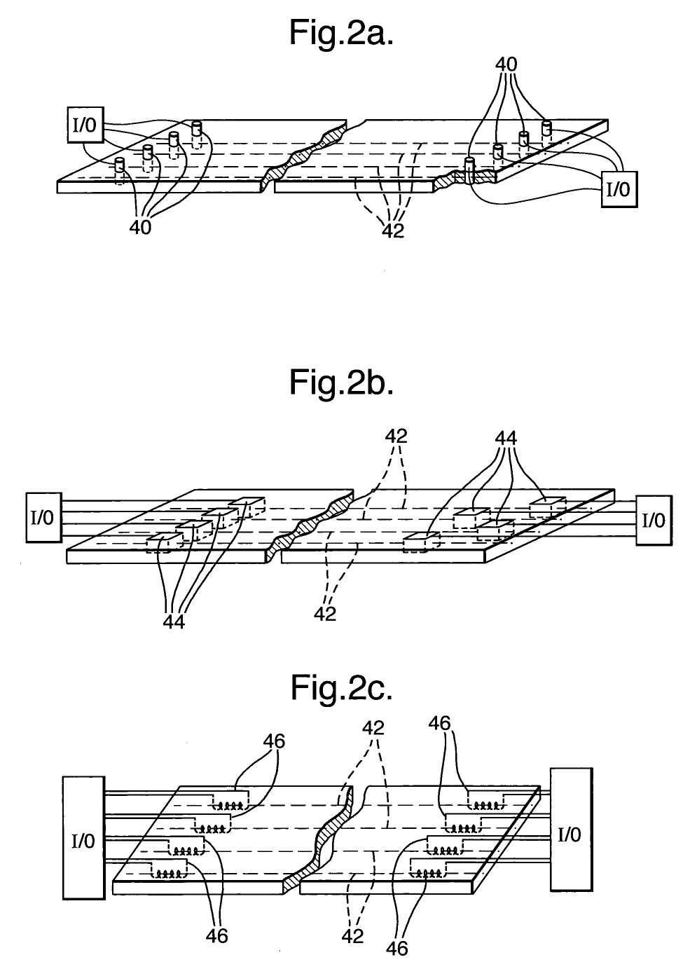

FIGS. 2a to 2c are detailed views of various coupling configurations for use in embodiments of the invention, using ohmic, and contactless capacitative and inductive coupling respectively;

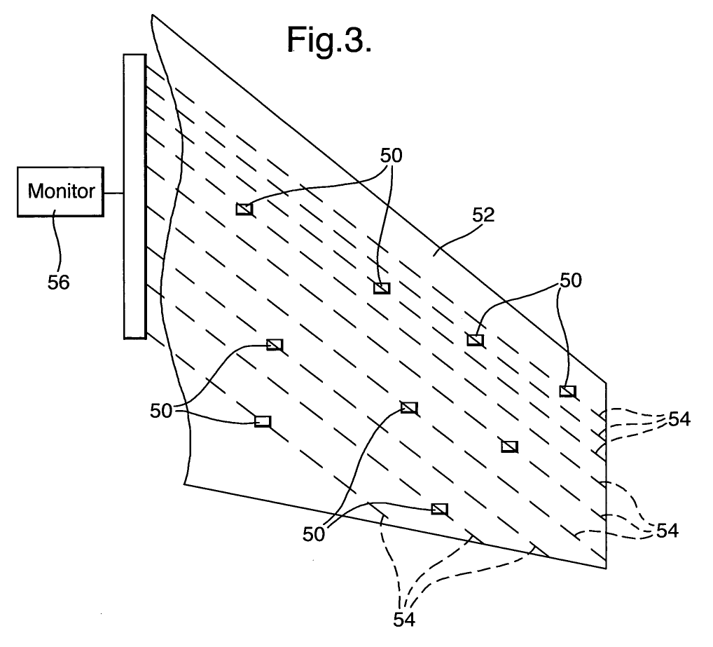

FIG. 3 is a schematic view of the use of an arrangement of this invention for monitoring sensors over an extended surface area of an aircraft; and

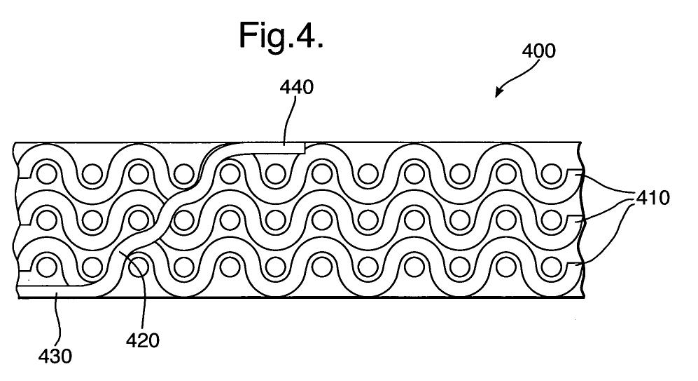

FIG. 4 is a schematic cross section through a further hybrid weave of this invention.

In the following examples, a hybrid weave material is provided with spaced electrically conducting fibres so that a fibre composite material can be made which has electrically conducting fibres running through it to provide electrically conducting tracks for signals, power etc. In this way, a fibre composite structure can be provided in which the interface between the external fibre and the matrix material is unaffected, with the electrically conducting region being housed fully within the fibres.

### EXAMPLE 1

A hybrid weave is made up in the warp direction of alternate tows of glass fibres (non-conducting) and carbon fibres (conducting), with the weft being made up of one or more tows of glass fibre. This provides a woven fabric material in which alternate warp tows define parallel, insulated, electrically conducting tracks in the warp direction. This fabric may be used as a flexible fabric with or without layers of surrounding material, or it may be impregnated with a suitable matrix material to form a composite.

A signal may be electrically coupled to the material so that the tracks form part of an electrical circuit. In one arrangement, a fibre composite material comprising parallel conducting tracks as described above is used to pass data signals in USB format from a Web Cam to a laptop to illustrate that the electrically conducting tracks are able to pass data along the composite material to be reconstituted on the laptop. A Web Cam having a USB connector is connected with the USB terminals electrically connected to respective tracks on a composite material. Some distance away from the Web Cam connector is a further USB connector whose terminals are connected to the corresponding conducting tracks so that the signals passed to a USB plug which is connected to a laptop. The Web Cam USB signals pass along the composite material and the images viewed on the laptop monitor.

### EXAMPLE 2

A screened connector is made up by laying up a stack of layers of material as shown in FIG. 1. A layer 10 of the hybrid material as described above having conducting tows 12 and non-conducting tows 14 arranged alternately in the warp direction, and an insulating weft tow 16, is located in the middle of the stack, sandwiched between two layers of conventional woven glass fibre fabric 18 acting as insulators. Two layers of conducting material 20 are then applied as the uppermost and lowermost layers. The conducting material 20 could be a woven carbon fibre material to provide a two-dimensional electrically conducting screen or grid of interconnected electrically conducting fibres. If further screening is required, then alternate conducting tows 12 may be grounded as shown to provide enhanced screening.

The electrical properties of the structure may be further tuned by suitable selection of the electrically conducting and non-conducting tows, the matrix material etc.

There are a number of different ways in which the conducting elements may be electrically coupled to other circuitry or components. For example as shown in FIG. 2a the coupling may be ohmic, for example by providing terminals 40 that are in direct physical contact with the conducting fibres 42 and which extend out of the composite. Alternatively, as shown in FIGS. 2b and 2c the coupling may be contactless, by means of a capacitative or inductive coupling elements 44 or 46. An advantage of such an arrangement is that the coupling elements may be re-sited as necessary to reconfigure the electrical circuit if, for example, the original conducting fibre is damaged. The coupling elements could take the form of adhesive pads that can be bonded to the composite material permanently or semi-permanently to provide the required electrical coupling with the underlying conducting fibres.

The circuits so formed may be used for numerous purposes other than conventional power supply or data transfer. Thus for example, as shown in FIG. 3, in aerodynamic studies or for aerodynamic control purposes, an array of surface sensors 50 may be provided on an exposed surface of a composite element 52 on an aircraft to detect one or more parameters relating to the structure and/or aerodynamic environment and connected to monitoring equipment 56 by the electrically conducting fibres 54 within the composite element. The use of inductive or capacitive coupling between the sensors 50 and the electrically conducting fibres 52 allows easy reconfiguration and setup.

The provision of an array of conductors on the composite allows redundancy to be built in so that a circuit can be rerouted if required. The conductors could be used to heat the composite material and thus provide de-icing, or to allow the infrared signature of a body to be modified.

### EXAMPLE 3

FIG. 4 is a schematic cross section through a composite structure 400 in accordance with a further embodiment of the invention. Structure 400 comprises a number of layers of fabric 410, each of which may be a conventional, non-conducting layer, or may be a layer comprising a number of conducting tows arranged as described above. In addition, a further conducting tow 420 is provided. Tow 420 extends through the thickness of the composite structure, perpendicular to the plane of layers 410, and is electrically isolated from any other conductive tows extending through the hybrid material layers 410. Contact pads 430, 440 are provided at the ends of tow 420. Each pad 430, 440 comprises a metallised region on an external surface of the structure 400. Such through-thickness conductive tows can be woven through several layers of hybrid fabrics, such as the hybrid fabrics described above, before resin impregnation. The conductive tows can be woven in manually, or stitched in by machine. Electrical isolation from other tows is ensured by appropriate placement of tow 420, away from other, in-plane conductive tows.

Such through-thickness conductive channels are particularly desirable where the resulting composite structure is to be used for an application in which mechanical strength is important, or where it is important to form a good seal between different ambient environments on either side of the structure (for example where the structure forms part of a fuel tank). Conventional connectors require an aperture to be cut in the composite structure, causing degradation of the mechanical properties of the structure, and creating a need for the structure to be re-sealed if necessary. The present embodiment allows multiple electrical connections to be formed through the thickness of composite structures without such problems. In fact, it is expected that the mechanical strength of structures incorporating such through thickness conductive tows may be improved in a manner similar to improvements achieved using ‘z-pinning’. It will therefore be appreciated that such through-thickness conductive tows may also be desirable in materials where ‘in-plane’ conductive fibres or tows are not present.

1. A hybrid material comprising,
a plurality of spaced electrically conducting fibres extending in a first direction and isolated from other like conducting fibres; and
a plurality of electrically insulating fibres extending in a second direction, thereby to define a material having a plurality of insulated electrically conducting tracks extending in a first direction.

2. A hybrid material according to claim 1, wherein said hybrid material is woven, said spaced electrically conducting fibres are warp fibres and said insulating fibres extending in the second weave direction are weft fibres.

3. A hybrid material according to claim 2, wherein said electrically conducting warp fibres are interposed by electrically insulating fibres to provide a periodic or an aperiodic structure.

4. A hybrid material according to claim 1, wherein said electrically conducting fibres comprise one or more of carbon fibres, metal plated fibres, and metallised fibres.

5. A fibre composite material made up of a hybrid material according to claim 1, and a matrix material.

6. A fibre composite material according to claim 5, wherein said matrix material comprises a polymeric, elastomeric, metal or ceramic material or a mixture of these.

7. A fibre composite material as claimed in claim 5, comprising a plurality of layers of said hybrid material, and at least one conductive fibre extending through the thickness of the composite material.

8. A fibre composite material as claimed in claim 7, arranged such that electrical connections can be made to both ends of the conductive fibre.

9. A fibre composite material, according to claim 5, of rigid sheet form defining a plurality of electrically conducting tracks each for the passage of data, power, control signals or a combination of these.

10. A transmission line for electrical signals, said transmission line including a multilayer structure including a layer of hybrid material according to claim 1 defining a plurality of insulated electrically conducting tracks, and one or more electrically insulating layers disposed adjacent to said hybrid material layer.

11. A transmission line according to claim 10, including at least one layer of electrically insulating material provided to either side of said hybrid material layer thereby to sandwich said hybrid material layer.

12. A transmission line according to claim 10, including at least one screening layer of electrically conductive material disposed adjacent the outermost electrically insulating layer and remote from the hybrid material layer.

13. An electrical circuit assembly comprising in combination a hybrid material according to with spaced electrical components electrically coupled by said one or more electrically conducting tracks.

14. An electrical circuit assembly according to claim 13, wherein said electrical components each have respective digital input/output terminals for inputting and/or outputting a digital signal, and the assembly comprises a plurality of conducting fibres passing digital signals between said digital input/output terminals.

15. (canceled)

16. A hybrid material comprising a plurality of electrically insulating fibres extending in first, warp direction, a plurality of electrically insulating fibres extending in a second, weft direction, and at least one electrically conducting fibre extending in a third direction generally perpendicular to the first and second directions, such that an electrical connection can be made across the hybrid material.
